(19) United States
(12) Patent Application Publication
(10) Pub. No.: US 2013/0248769 A1
(43) Pub. Date: Sep. 26, 2013

(54) METAL PASSIVATION OF HEAT-EXCHANGER EXPOSED TO SYNTHESIS GAS

(71) Applicants: Peter Edward James Abbott, Eaglescliffe (GB); Martin Fowles, Whitby (GB)

(72) Inventors: Peter Edward James Abbott, Eaglescliffe (GB); Martin Fowles, Whitby (GB)

(73) Assignee: JOHNSON MATTHEY PLC, London (GB)

(21) Appl. No.: 13/821,768

(22) PCT Filed: Aug. 19, 2011
(86) PCT No.: PCT/GB2011/051574

§ 371 Date: Jun. 3, 2013

(30) Foreign Application Priority Data
Sep. 9, 2010 (GB) 1015021.7

(51) Int. Cl. C23C 16/30

(52) U.S. Cl. CPC C23C 16/30
USPC 252/373; 422/162; 422/291; 427/248.1

(57) ABSTRACT

A process is described for the passivation of the surfaces of heat exchange apparatus exposed to a synthesis gas containing carbon monoxide and hydrogen, including the steps of:
(i) adding an arsenic compound to the synthesis gas at a temperature ≧850° C. to generate volatile arsenic passivation species,
(ii) exposing the mixture of hot synthesis gas and arsenic passivation species to surfaces on the shell-side of said heat exchange apparatus to reduce the interaction between the carbon monoxide present in said gas and metals said in said surfaces,
(iii) recovering a cooled synthesis gas from the shell-side of said apparatus, and
(iv) passing the cooled synthesis gas, optionally after further cooling, through a sorbent bed to remove arsenic compounds from the synthesis gas.

### CROSS-REFERENCE TO RELATED APPLICATIONS

This application is the U.S. National Phase application of PCT International Application No. PCT/GB2011/051574, filed Aug. 19, 2011, and claims priority of British Patent Application No. 1015021.7, filed Sep. 9, 2010, the disclosures of both of which are incorporated herein by reference in their entireties for all purposes.

### FIELD OF THE INVENTION

This invention relates to methods for passivating metal surfaces in apparatus subjected to carbon monoxide-containing gases and in particular to methods for reducing methanation reactions, shift reactions and carburization reactions in heat exchange apparatus exposed to synthesis gases.

### BACKGROUND OF THE INVENTION

Synthesis gases may be formed by steam reforming, partial oxidation and/or a combination thereof. Thus, pre-reforming and autothermal reforming or primary steam reforming and autothermal or secondary reforming may be used to generate synthesis gases suitable for the production of methanol, dimethyl ether, hydrogen, and hydrocarbons by the Fischer-Tropsch reaction.

The synthesis gases recovered from the reforming apparatus may be cooled before downstream processing using various techniques. In one method, the hot secondary reformed gas mixture is passed through the shell side of a heat exchange reformer containing a plurality of catalyst filled tubes to provide the heat for the primary reforming step. The resulting partially cooled secondary reformed gas mixture may be subjected to one or more further stages of heat exchange. Alternatively the hot, reformed gas mixture may be fed to a waste heat boiler and then used to generate superheated steam before being cooled further in stages of heat exchange.

Such heat exchange apparatus typically is fabricated using alloys that comprises metals such as Ni, Cr and Fe, which under the conditions present in the apparatus, are able to interact with carbon monoxide in the synthesis gas to produce undesirable side reactions including methanation, water-gas shift, and the corrosive carburization reactions, which give rise to so-called “metal dusting.” Whereas higher grade alloys may be used to reduce this problem, these can be costly to use in large reformers. Lower grade alloys may be used if their surfaces are passivated. Passivation of the metal surfaces in heat exchange equipment has been performed in an attempt to prevent the undesirable reactions from taking place.

WO 2007/049069 describes a method for passivating low-alloy steel surfaces in apparatus operating in the temperature range 350 to 580° C. and exposed to a carbon monoxide containing gas mixture comprising adding a passivating compound containing at least one phosphorus (P) atom to said gas mixture.

WO 03/051771 describes a method for reducing the interaction between carbon monoxide present in a heat exchange medium and metal surfaces on the shell side of heat exchange reformer apparatus used for producing a primary reformed gas by treatment of the shell-side of said apparatus with an effective amount of at least one passivation compound containing at least one atom selected from phosphorus, tin, antimony, arsenic, lead, bismuth, copper, germanium, silver, or gold.

Whereas the phosphorus compounds tested were effective in reducing the interaction of carbon monoxide with the alloy surfaces, there is a need to improve the passivation at higher temperatures and under more aggressive synthesis gas compositions.

### SUMMARY OF THE INVENTION

Whereas the aforesaid WO 03/051771 suggests that arsenic compounds may be used, we have found that it is necessary to use a high-temperature synthesis gas stream to achieve acceptable passivation. Moreover, in view of the severe poisoning effects of arsenic on downstream catalysts, it is necessary to use a sorbent to capture any arsenic that is not retained on the passivated surfaces.

Accordingly, the invention provides a process for the passivation of the surfaces of heat exchange apparatus exposed to a synthesis gas containing carbon monoxide and hydrogen, comprising the steps of:
(i) adding an arsenic compound to the synthesis gas at a temperature ≧850° C. to generate volatile arsenic passivation species,
(ii) exposing the mixture of hot synthesis gas and arsenic passivation species to surfaces on the shell-side of said heat exchange apparatus to reduce the interaction between the carbon monoxide present in said gas and metals in said surfaces,
(iii) recovering a cooled synthesis gas from the shell-side of said apparatus, and
(iv) passing the cooled synthesis gas, optionally after further cooling, through a sorbent bed to remove arsenic compounds from the synthesis gas.

The invention also provides apparatus suitable for performing the process.

### BRIEF DESCRIPTION OF THE DRAWINGS

The invention will further be described by reference to the drawings in which;

FIG. 1 depicts a process flow-sheet according to one embodiment of the present invention, and

FIG. 2 depicts a process flow-sheet incorporating an alternative embodiment of the present invention.

### DETAILED DESCRIPTION OF THE INVENTION

The heat exchange apparatus may be a steam generating heat exchange apparatus such as a waste heat boiler and/or steam superheater, or a heat exchanger used to heat a fuel gas, hydrocarbon stream or oxygen-containing gas used in the reforming process to generate the synthesis gas. In particular, steam superheaters and gas-gas-interchangers may be protected using the method of the present invention. Such heat exchange apparatus is well known and is typically installed downstream of conventional fired primary reformers and/or autothermal reformers.

In one embodiment, the passivation technique is applied to one or more heat exchangers, used to recover heat from a synthesis gas generated in a reforming process comprising subjecting a hydrocarbon feedstock/steam mixture to at least one stage of adiabatic steam reforming, also known as pre-reforming, over a supported nickel catalyst and passing the pre-reformed gas fed to an autothermal reformer where it is partially combusted with an oxygen-containing gas and the partially combusted gas passed through a bed of steam reforming catalyst.

Alternatively the heat exchange apparatus may be a heat exchange reformer heated with a synthesis gas, also know as a gas-heated reformer. In such heat exchange reformer apparatus, a mixture of hydrocarbon and steam is passed from a process fluid feed zone, through vertical heat exchange tubes containing a particulate catalyst, disposed within a heat exchange zone defined by a shell through which a heat exchange medium passes, and then into a process fluid off-take zone. Gaseous heat exchange medium flows through the shell around the outside of the heat exchange tubes which may have sheath tubes surrounding them for a part of their length. Heat exchange reformers of this type are described in GB1578270, and WO97/05947. Another type of gas-heated heat exchange reformer apparatus that may be used is a double-tube heat exchange reformer as described in U.S. Pat. No. 4,910,228 wherein the reformer tubes each comprise an outer tube having a closed end and an inner tube disposed concentrically within the outer tube and communicating with the annular space between the inner and outer tubes at the closed end of the outer tube with the steam reforming catalyst disposed in said annular space. Heat exchange medium flows around the external surface of the outer tubes. In this embodiment, the heat exchange medium is a synthesis gas. In particular, the synthesis gas may be derived from a primary reformed gas mixture recovered from the catalyst-filled-tubes, which is then subjected to further processing in a secondary reformer. In the secondary reformer, the primary reformed gas is subjected to partial combustion with an oxygen containing gas in a burner, which raises its temperature, and the partially combusted gas passes through a bed of steam reforming catalyst, disposed beneath the burner.

The shell side of the heat exchange apparatus is taken to include all the surfaces within the shell of the apparatus that are exposed to the synthesis gas. This includes the inside of the shell and in particular the outer surfaces of tubes within the heat exchange apparatus. For example, in heat exchange reformer apparatus, the shell side includes the inner surface of the shell defining the heat exchange zone, the outer surfaces of heat exchange tubes, the outer surfaces of any fins attached to the heat exchange tubes to increase their heat transfer area, the surfaces of any sheath tubes surrounding the heat exchange tubes, the surfaces of any tube-sheets defining the boundaries of said heat exchange zone and which are exposed to heat exchange medium, and the outer surfaces of any header pipes within said heat exchange zone.

The method of the present invention requires the treatment of the shell side of heat exchange apparatus. By treatment we mean coating of the metal surfaces on the shell side of the heat exchange apparatus with one or more arsenic passivation compounds and any other compounds that may be added to improve the effectiveness of the passivation compounds, herein termed augmenting compounds. Because of the high temperatures within heat exchange apparatus in use, the passivation compounds and any augmenting compounds will generally undergo a thermal transformation resulting in the formation of one or more passivation species that reduce the interaction between carbon monoxide present in the synthesis gas and catalytically active metals in the surfaces on the shell side of the heat exchange apparatus.

The arsenic compound may be any suitably vaporizable arsenic compound. Elemental arsenic, arsenic (III) oxide (As₂O₃), arsenic (V) oxide (As₂O₅), arsenic acid (H₅As₃O₁₀), monoethylarsine, trimethylarsenic, triethylarsenic, diethylarsine, dimethylarsine, phenylarsine, tertiary-butylarsine, and dimethylaminoarsenic are suitable as having a lower toxicity than arsine, high vapor pressure, low temperature stability, pyrolysis at temperatures of 400° C. or higher, and no inherent purity limitations such as excess carbon contamination. Preferably the arsenic compounds are solids, more preferably the arsenic compounds are selected from one or more of elemental arsenic, arsenic (III) oxide (As₂O₃), arsenic (V) oxide (As₂O₅) and arsenic acid (H₅As₃O₁₀). Most preferably the arsenic compound comprises As₂O₃ or As₂O₅.

When combined with the synthesis gas comprising hydrogen at temperature ≧850° C., the arsenic compounds are capable of generating arsine (AsH₃) and other arsenic passivation species such as AsO and As metal vapor in situ.

The synthesis gas that is contacted with the arsenic passivation compound should be at a temperature ≧850° C., preferably ≧875° C., most preferably ≧900° C., in order to generate a sufficient passivation species concentration in the synthesis gas. The arsenic passivation species then reduces the interaction between the carbon monoxide present in said synthesis gas and the catalytically-active metals on the shell side of the heat exchange apparatus. The temperature in the shell-side of the heat exchange apparatus may be lower than the temperature at which the arsenic compound is contacted with the synthesis gas, e.g. in the range 500-850° C. due to heat losses including the effect of the heat exchange itself.

The arsenic passivation species may be formed by adding a liquid arsenic compound or a solution of the compound directly to the synthesis gas. Solid arsenic compounds such as elemental arsenic, arsenic (III) oxide (As₂O₃), arsenic (V) oxide (As₂O₅), or arsenic acid (H₅As₃O₁₀) are preferably added as a dispersion or solution in water or other suitable liquid to the synthesis gas.

A dispersion or solution of arsenic oxide in water is a preferred passivation species precursor. Arsenic (III) oxide is slightly soluble in cold water and is relatively soluble in boiling water. Steam may therefore be used to dissolve the As(III) oxide and prepare a solution of the arsenic oxide. Arsenic (V) oxide is soluble in water to higher concentrations.

Concentrations of arsenic compound in water in the range 0.1-10 wt % are preferred. Surfactants and/or solvents may be added to the dispersions/solutions to improve dispersal.

Augmenting compounds may optionally be added with the arsenic compound in order to improve the ability of the arsenic passivation species to reduce side reactions. Augmenting compounds preferably contain at least one atom selected from phosphorus, tin, antimony, lead, bismuth, copper, germanium, silver or gold, aluminium, gallium, chromium, indium, or titanium. Suitable augmenting compounds include inorganic compounds comprising oxides and oxo compounds, including hydrous oxides, oxo-acids and hydroxides, sulphides, sulphates, sulphites, phosphates, phosphites, carbonates, or nitrates, and metal-organic compounds, comprising metal carboxylates, thiocarboxylates, or carbamates, metal alkyl- or arylsulphonates, metal alkyl- or arylphosphates esters, metal alkyl- or arylphosphonates or thiophosphonates, metal alkyls, metal aryls, metal alkoxides and aryloxides, and chelated compounds.

In the present invention, the treatment of the shell side of the heat exchange apparatus is by addition of the passivation compound and any augmenting compound, if used, to the synthesis gas. This addition may be continuous or periodic. It is preferable, when addition is continuous, that the addition rate is such that the temperature of the synthesis gas is not reduced by more that 10 degrees centigrade, in order not to impact on the performance of the heat exchange apparatus. Alternatively where the addition of passivation compound is periodic, a greater temporary reduction in temperature of the synthesis gas may be tolerated.

A particularly preferred means for adding the arsenic compound and any augmenting compound to the synthesis gas is using a steam atomiser. A steam atomiser comprises two concentric tubes; the arsenic compound dispersion or solution is provided at a controlled flow rate by the central tube and steam is provided via the annulus formed by the outer tube to carry the arsenic compound into the synthesis gas. Using a steam atomiser has the advantage that it creates extremely small droplets for good mass and heat transfer. Furthermore, the steam in the outer annulus keeps the outer wall and tip of the atomiser relatively cool and thus inhibits corrosion and prevents fouling and coking.

The amount of the arsenic compound used is preferably such that the As content in the synthesis gas entering the shell side of the heat exchange apparatus is in the range 0.01 to 200 ppmv, preferably 0.01 to 10 ppmv, more preferably 1 to 10 ppmv. If a phosphorus, tin, antimony, lead, bismuth, copper, germanium, silver or gold, aluminium, gallium, chromium, indium, or titanium-containing augmenting compound is also used, these elements are desirably present in the synthesis gas at a level between 0.01 and 10 ppm by volume.

It has been found that beneficial effects are observed where the shell side of the heat exchanger apparatus is subjected to a pre-treatment with an arsenic compound in an inert gas stream at a temperature ≧500° C., preferably ≧750° C., more preferably ≧850° C. The pre-treatment may reduce the amount of arsenic required to be added with the synthesis gas. Suitable inert gases are methane, carbon dioxide, and especially nitrogen. The As concentration in the inert gas is preferably in the range 0.01 to 200 ppmv, preferably 0.01 to 10 ppmv.

The shell side of the heat exchange apparatus may be treated by either a continual or periodic addition of the arsenic compound and any augmenting compound to the synthesis gas. Continual low-level addition may be preferable to periodic higher level addition in preventing the undesired side reactions.

Because arsenic species are potent catalyst poisons capable of deactivating catalysts in subsequent process steps, the present invention provides means downstream of the heat exchange apparatus to recover the volatile arsenic species to prevent contamination of subsequent processes or poisoning of catalysts in any subsequent process steps. Such apparatus may comprise a fixed bed of a particulate sorbent material or monolithic sorbent structures arranged in a suitable vessel. The sorbent may be applied to the synthesis gas at high temperature, typically ≧200° C., or at a lower temperature, typically ≦200° C., optionally after removal of any process condensate. Suitable sorbents for arsenic species include supported precious metal sorbents, such as supported Pd compositions, and copper-, iron-, and/or manganese-compounds. The means to recover volatile arsenic species preferably comprises a copper-containing sorbent. In particular, copper compounds such as copper oxide and basic copper carbonate, which may be combined with one or more supports and or binder materials, have been found to be particularly effective for trapping arsenic. Under the reducing conditions provided by the synthesis gas, the copper in the sorbent may be reduced to an elemental state in situ. A particularly suitable copper-containing sorbent is PURASPEC™ 2088 available from Johnson Matthey Catalysts.

In order that the copper-containing sorbent does not promote undesired side reactions, it is preferable to cool the synthesis gas exiting the heat exchange apparatus to ≦200° C., preferably ≦150° C., and remove any process condensate that may have formed before passing the synthesis gas over the sorbent to remove the As. Any As in the condensate may be removed using suitable materials such as sieves or ion-exchange resins.

Effective treatment of the shell side of apparatus according to the method of the present invention results in a reduction of the undesirable carbon monoxide reactions that can occur. The reduction may be observed by monitoring the methane and/or carbon dioxide levels in the synthesis gas pre- and post-treatment. The reduction in methane and carbon dioxide that may be achieved depends on the quantity and nature of the passivation compounds, the fabrication alloy of the heat exchange medium, as well as the method of treatment of the heat exchange apparatus and the carbon monoxide content of the synthesis gas. Typically, reductions in the range 5-100% of methane and/or carbon dioxide content may be observed.

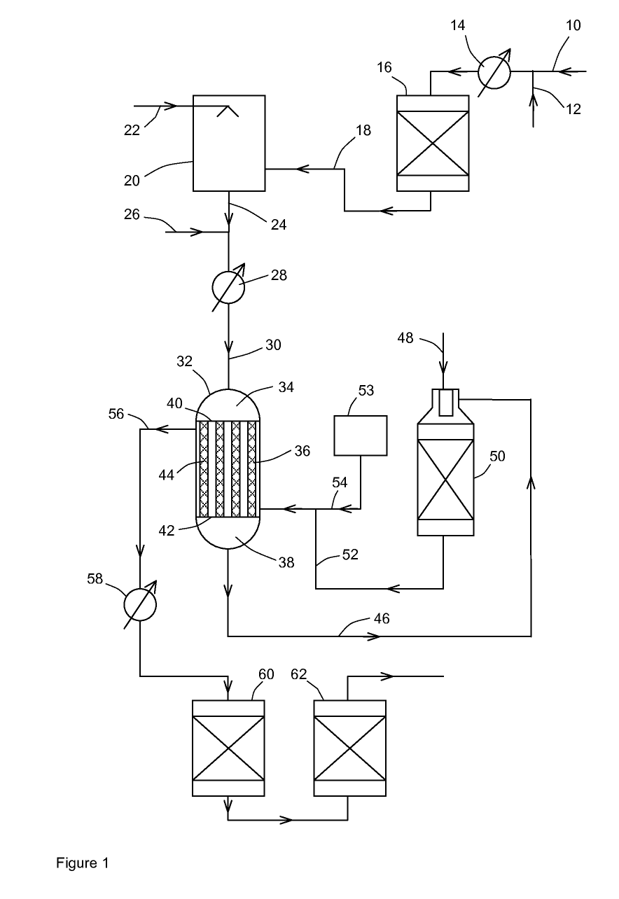

In FIG. 1, natural gas at an elevated pressure, typically in the range 15 to 50 bar abs., is fed via line 10 and mixed with a small amount of a hydrogen-containing gas fed via line 12. The mixture is then heated in heat exchanger 14 and fed to a desulphurisation stage 16 wherein the gas mixture is contacted with a bed of a hydro-desulphurisation catalyst, such as nickel or cobalt molybdate, and an absorbent, such as zinc oxide, for hydrogen sulphide removal. The desulphurised gas mixture is then fed, via line 18, to a saturator 20, wherein the gas contacts a stream of heated water supplied via line 22. The saturated gas leaves the saturator via line 24 and may if desired be subjected to a step of low temperature adiabatic reforming (not shown) before being mixed with recycled carbon dioxide supplied via line 26 and heated in heat exchanger 28 to a heat exchange reformer inlet temperature. The heated process gas is fed from exchanger 28, via line 30, to the catalyst-containing tubes of a heat exchange reformer 32. The heat exchange reformer has a process fluid feed zone 34, a heat exchange zone 36, a process fluid off-take zone 38 and first 40 and second 42 boundary means separating said zones from one another. The process fluid is subjected to steam reforming in a plurality of heat exchange tubes 44 containing a steam reforming catalyst to give a primary reformed gas stream. Only 4 tubes are shown; it will be well understood by those skilled in the art that in practice there may be tens or hundreds of such tubes. The primary reformed gas stream is passed from said heat exchange tubes 44 to the process fluid off-take zone 38, and then via line 46 to further processing. The further processing comprises secondary reforming in an autothermal reformer 50 in which the primary reformed gas mixture is subjected to partial combustion with an oxygen-containing gas, supplied via line 48 to a burner disposed above a bed of secondary reforming catalyst. The resultant secondary reformed synthesis gas is passed via line 52 to heat exchange zone 36 as the heat exchange medium.

Passivation compound feed apparatus 53 feeds a dispersion of arsenic compound, e.g. As(III) oxide, via line 54 to the secondary reformed synthesis gas in line 52 in order to disperse an arsenic species effective for passivation within the synthesis gas prior to entry to the heat exchange zone 36. The amount of oxygen fed to the autothermal reformer 50 is controlled so that the temperature of the synthesis gas in line 52 is ≧850° C.

The passivation compound feed apparatus preferably comprises a tube, fed by a suitable metering pump from a reservoir of arsenic oxide in water, inserted into the synthesis gas feed line. The tube typically may have a nozzle having a plurality of small holes so that the arsenic compound is introduced in the form of small droplets or an aerosol that is readily dispersed. In one embodiment, the compound is introduced by steam atomisation in which steam is introduced in a co-axial, annular tube around a passivation compound feed tube. In this way the nozzle can be designed to mix the steam and mixture of arsenic compound in water at a nozzle to give a fine droplet dispersion.

The high temperature of the synthesis gas causes decomposition of the arsenic compound to form arsenic passivation species in the synthesis gas.

The synthesis gas containing the arsenic passivation species passes up through the spaces between the heat-exchange tubes thereby supplying the heat required for the primary reforming and exits the reactor as a partially-cooled synthesis gas via line 56. The arsenic passivation species are deposited upon the outer surfaces of the heat exchange tubes 44 and other surfaces within the shell side of the heat exchange zone 36. The reformed gas in line 56 is then cooled in one or more heat exchangers 58, including one or more waste heat boilers, steam superheaters and gas-gas-interchangers.

Any volatile arsenic compounds passing through the shell side of the heat exchange reformer 32 are removed by passing the cooled reformed gas, after cooling to below 200° C. and removal of condensate (not shown) through a reduced copper-sorbent disposed in vessels 60 and 62. These vessels may be arranged such that when the beds within 60 become saturated, the reformed gas is fed directly to vessel 62 and vessel 60 is taken off-line and replenished with fresh sorbent. When vessel 60 has been replenished, it is re-introduced into the process line as the downstream vessel in readiness for when the beds in vessel 62 become saturated.

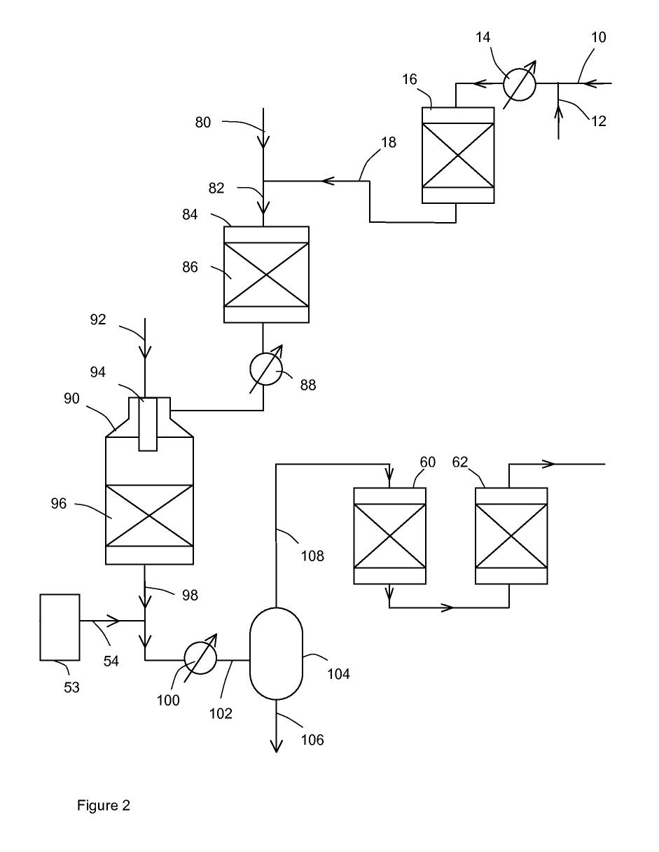

In FIG. 2, natural gas at an elevated pressure, typically in the range 15 to 50 bar abs., is fed via line 10 and mixed with a small amount of a hydrogen-containing gas fed via line 12. The mixture is heated in heat exchanger 14 and fed to a desulphurisation stage 16 wherein the gas mixture is contacted with a bed of a hydro-desulphurisation catalyst, such as nickel or cobalt molybdate, and an absorbent, such as zinc oxide, to remove hydrogen sulphide. The desulphurised gas mixture from the HDS unit 16 in line 18 is mixed with steam in line 80 and the resulting desulphurised natural gas/steam mixture 82 subjected to a step of adiabatic low temperature reforming in pre-reformer 84 containing a bed of pre-reforming catalyst 86. In the pre-reforming stage, the desulphurised natural gas/steam mixture is heated to a temperature in the range 350-650° C., preferably 400-650° C., and passed adiabatically through a bed of a supported nickel catalyst. During such an adiabatic low temperature reforming step, any hydrocarbons higher than methane react with steam to give a mixture of methane, carbon oxides and hydrogen. After the pre-reforming step, the pre-reformed gas mixture is heated, in heat exchanger 88 and fed to an autothermal reformer 90. In the autothermal reformer, the pre-reformed gas, which may be mixed with a recovered carbon dioxide stream and/or tail gas from downstream processing, is first subjected to a step of partial combustion with an oxygen containing gas fed via line 92 in burner 94. Whereas some steam may be added to the oxygen containing gas, preferably the amount is minimised so that a low overall steam ratio for the reforming process is achieved. The gas containing free oxygen is preferably substantially pure oxygen, e.g. oxygen containing less than 5% nitrogen. However where the presence of substantial amounts of inerts is permissible, the gas containing free oxygen may be air or enriched air. Where the gas containing free oxygen is substantially pure oxygen, for metallurgical reasons it is preferably fed to the autothermal reformer at a temperature below about 250° C.

The amount of oxygen fed to the partial combustion stage may be varied to effect the composition of the reformed gas mixture. The amount of oxygen-containing gas added is preferably such that 40 to 70, preferably 40 to 60, moles of oxygen are added per 100 gram atoms of carbon in the hydrocarbon feedstock. The partial combustion reactions may raise the gas temperature of the gas mixture to between 1000 and 1700° C.

The hot partially combusted gas then passes though a fixed bed of steam reforming catalyst 96 disposed beneath the burner 94 in the autothermal reformer 90 to form the synthesis gas mixture. The steam reforming catalyst may be nickel and/or ruthenium supported on a refractory support such as rings or pellets of calcium aluminate cement, alumina, titania, zirconia, and the like. The partially combusted gas is cooled as it passed through the bed of steam reforming catalyst. As stated above, the temperature of the reformed gas may be controlled by the amount of oxygen added for the partial combustion step. Preferably the amount of oxygen added is such that the autothermally reformed synthesis gas mixture leaves the steam reforming catalyst at a temperature in the range 850-1050° C. The hot synthesis gas is recovered from the autothermal reformer via line 98.

Passivation compound feed apparatus 53 feeds a dispersion of arsenic compound, e.g. As(III) oxide via line 54 to the autothermally reformed synthesis gas in line 98 in order to disperse an arsenic species effective for passivation within the synthesis gas.

The high temperature of the synthesis gas causes decomposition of the arsenic compound to form arsenic passivation species in the synthesis gas.

The synthesis gas/As species mixture then passes to one or more heat exchangers including one or more waste heat boilers, steam superheaters and gas-gas-interchangers 100. The undesired side reactions between carbon monoxide and the alloys used in the shell side of the waste heat boiler are prevented or reduced by the arsenic passivation species present in the synthesis gas mixture.

The cooled synthesis gas mixture is cooled to below the dew point of steam at which water condenses. The cooled synthesis gas is fed via line 102 to a separator 104, which separates process condensate via line 106. The resulting de-watered synthesis gas contains volatile arsenic species and so is fed from the separator 104 via line 108 to sorbent vessels 60 and 62 containing a suitable copper-based sorbent that removes arsenic compounds from the synthesis gas.

### EXAMPLES

The invention will be further described by way of the following examples.

### Example 1

### Comparison of P and As

In a calculated example, the vapor pressure and loss of volatile species from intermetallic nickel-arsenic alloys under conditions typical in the shell side of a heat exchange reformer were determined. The results may be compared with phosphorus intermetallic compounds as follows;

| Element | P | As |
|---|---|---|
| Intermetallic | Ni₅P₂ | Ni₅As₂ |
| Volatile Species | P₄O₆ | AsH₃ |
| 900K (Vapor pressure | 2.50 × 10⁻¹⁰ | 2.00 × 10⁻¹⁰ |
| atm) | | |
| Loss g (element)/hr | 1.21 × 10⁻³ | 5.85 × 10⁻⁴ |
| Loss 1000 hrs (g) | 1.21 × 10⁰ | 5.85 × 10⁻¹ |
| 1000K (Vapor pressure | 3.00 × 10⁻⁹ | 1.90 × 10⁻⁹ |
| atm) | | |
| Loss g (element)/hr | 1.45 × 10⁻² | 5.56 × 10⁻³ |
| Loss 1000 hrs (g) | 1.45 × 10¹ | 5.56 × 10⁰ |

The calculations assume p(H₂O)=9.3 atm, p(H₂)=20.9 atm and flowrate of heat exchange medium is 1560 kmol per hour. The intermetallic cited is the most stable species under the conditions. The calculations show As-compounds to be more effective than P-compounds in producing a stable intermetallic alloy with Ni that will suppress carbon monoxide reactions and remain relatively involatile compared to phosphorus under typical operating conditions.

### Example 2

### As₂O₃ Treatment

23 test pieces (ca 2×2×2 mm) of alloy 601 were placed in a quartz tube and exposed to a synthesis gas mixture (reduction coefficient 0.023, Boudouard coefficient 0.015) at 1.8 mols/hr at 600° C. and 40 bar abs. The gas composition was as follows;

| H₂ | 54.4% volume |
|---|---|
| CO | 27.1% |
| CO₂ | 4.3% |
| H₂O | 13.2% |
| N₂ | 1.0% |
| CH₄ | 0.0% |

The synthesis gas was passed over the alloy 601 pieces at about 600° C. The reactions were monitored by measuring the concentrations of methane and carbon dioxide in the gas downstream of the test apparatus using an IR analyser. Within a few hours, a significant amount of methane was being generated due to metal dusting. The synthesis gas was replaced with dry nitrogen and a 0.05 wt % As₂O₃ solution injected into the nitrogen at 900° C. to give a level of about 2 ppmv As in the gas for 24 hours. At the end of 24 hours, the synthesis gas was reintroduced and the nitrogen feed stopped, with the injection of the 0.05 wt % As₂O₃ solution into the synthesis gas at 900° C., still at a concentration of about 2 ppmv. No methane formation was observed under these conditions for a further 4 days. After 4 days, the injection of 0.05 wt % As₂O₃ solution into the synthesis gas was stopped and the experiment continued for 2 further days with the synthesis gas passing over the alloy 601 at 600° C. with no observed methane formation.

The results show that As₂O₃ addition, equivalent to 2 ppmv As, to the synthesis gas at a temperature of 900° C. eliminated methane forming metal dusting reactions on alloy 601.

### Example 3

### As₂O₃ Treatment

16 test pieces (ca 2×2×2 mm) of alloy 601 were placed in a quartz tube and exposed to a synthesis gas mixture (reduction coefficient 0.023, Boudouard coefficient 0.015) at 1.8 mols/hr at about 800° C. and 40 bar abs. The gas composition was as follows;

| H₂ | 58.2% volume |
|---|---|
| CO | 29.0% |
| CO₂ | 4.6% |
| H₂O | 7.1% |
| N₂ | 1.1% |
| CH₄ | 0.0% |

The synthesis gas was passed over the alloy 601 pieces at about 600° C. for about 5 days, then gradually increased to 800° C. The reactions were monitored by measuring the concentrations of methane and carbon dioxide in the gas downstream of the test apparatus using an IR analyser. The level of methane formation started to climb steadily. After a further 7 days, a 0.05 wt % As₂O₃ solution was injected into the syngas at 800° C. to give a level of about 2 ppmv As in the gas. Over the following 3 days, the level of methane was reduced gradually by a factor of 6×, but the methane production did not subside completely, during longer term exposure.

The results show that As₂O₃ addition, equivalent to 2 ppmv As, to the synthesis gas at a temperature of 800° C. reduced, but did not eliminate, methane forming metal dusting reactions on alloy 601 at 800° C.

Examples 2 and 3 indicate that higher temperatures are required to generate sufficient passivation species to fully protect the alloy.

1. A process for the passivation of the surfaces of heat exchange apparatus exposed to a synthesis gas containing carbon monoxide and hydrogen, comprising the steps of:
(i) adding an arsenic compound to the synthesis gas at a temperature ≧850° C. to generate volatile arsenic passivation species,
(ii) exposing the mixture of hot synthesis gas and arsenic passivation species to surfaces on the shell-side of said heat exchange apparatus to reduce the interaction between the carbon monoxide present in said gas and metals said in said surfaces,
(iii) recovering a cooled synthesis gas from the shell-side of said apparatus, and
(iv) passing the cooled synthesis gas, optionally after further cooling, through a sorbent bed to remove arsenic compounds from the synthesis gas.

2. A process according to claim 1 wherein the heat exchange apparatus comprises steam generating heat exchange apparatus and/or a gas-gas interchanger.

3. A process according to claim 1 wherein the heat exchange apparatus comprises a heat exchange reformer used to generate a primary reformed gas mixture.

4. A process according to claim 3 wherein the primary reformed gas mixture is subjected to partial oxidation with an oxygen containing gas and secondary reforming to generate the synthesis gas.

5. A process according to claim 1 wherein the arsenic compound is selected from the group consisting of elemental arsenic, arsenic (III) oxide (As₂O₃), arsenic (V) oxide (As₂O₅) , arsenic acid (H₅As₃O₁₀), monoethylarsine, trimethylarsenic, triethylarsenic, diethylarsine, dimethylarsine, phenylarsine, tertiary-butylarsine and dimethylaminoarsenic.

6. A process according to claim 1 wherein the arsenic compound is selected from the group consisting of elemental arsenic, arsenic (III) oxide, arsenic (V) oxide and arsenic acid.

7. A process according to claim 1 wherein the As content in the synthesis gas is in the range 0.01 to 200 ppm by volume.

8. A process according to claim 1 wherein the arsenic compound is introduced into the synthesis gas by steam atomisation.

9. A process according to claim 1 wherein one or more augmenting compounds containing at least one augmenting atom selected from the group consisting of phosphorus, tin, antimony, lead, bismuth, copper, germanium, silver, gold, aluminium, gallium, chromium, indium, and titanium is combined with the synthesis gas.

10. A process according to claim 9 wherein the augmenting atom is present in the synthesis gas at a level between 0.01 and 10 ppm by volume.

11. A process according to claim 1 wherein the shell side of the heat exchanger apparatus is subjected to a pre-treatment with an arsenic compound in an inert gas stream at a temperature ≧500° C.

12. A process according to claim 11 wherein the inert gas is nitrogen.

13. A process according to claim 1 wherein the sorbent is a supported precious metal or copper-containing sorbent.

14. Apparatus comprising:
heat exchange apparatus having surfaces reactive with carbon monoxide present in a synthesis gas passed through the shell side of said apparatus,
means for adding an arsenic compound to the synthesis gas at a temperature ≧850° C. ,
means for recovering a cooled synthesis gas from the shell-side of said apparatus, and
a sorbent vessel, coupled to said heat exchange apparatus, though which the cooled synthesis gas, optionally after further cooling, is passed, said vessel containing a sorbent bed to remove any remaining arsenic compounds.

15. Apparatus according to claim 14 wherein the heat exchange apparatus comprises steam generating heat exchange apparatus and/or a gas-gas interchanger.

16. Apparatus according to claim 14 wherein the heat exchange apparatus comprises a heat exchange reformer used tol generate a primary reformed gas mixture.

17. Apparatus according to claim 16 further comprising a secondary reformer to which the primary reformed gas is connected, said secondary reformer comprising a burner for partial oxidation of said primary reformed gas with an oxygen containing gas to generate a partially oxidised gas mixture, and bed of secondary reforming catalyst disposed beneath the burner through which the partially oxidised gas mixture is passed to generate the synthesis gas.

18. Apparatus according to claim 14 wherein the means for adding the arsenic compound to the synthesis gas comprises a steam atomiser.

19. Apparatus according to claim 14 wherein the sorbent is a supported precious metal or copper-containing sorbent.

20. Apparatus according to claim 19 wherein the copper-containing sorbent is a particulate copper/zinc oxide/alumina composition.
